(19) United States
(12) Patent Application Publication
(10) Pub. No.: US 2025/0350066 A1
(43) Pub. Date: Nov. 13, 2025

(54) Connector Shell Assembly, Connector and Connector Assembly

(71) Applicant: Tyco Electronics (Shanghai) Co., Ltd., Shanghai (CN)

(72) Inventors: WenYu (Vindy) Liu, Shanghai (CN); Guangming (Suny) Zhao, Shanghai (CN); Jiwang (Arthur) Jin, Shanghai (CN); Bowen Yu, Shanghai (CN)

(73) Assignee: Tyco Electronics (Shanghai) Co., Ltd., Shanghai (CN)

(21) Appl. No.: 19/203,674

(22) Filed: May 9, 2025

(30) Foreign Application Priority Data
May 9, 2024 (CN) 202410573727.2

(51) Int. Cl. H01R 13/627; H01R 12/52; H01R 12/71; H01R 13/02; H01R 13/514; H01R 13/629; H05K 7/20

(52) U.S. Cl. CPC H01R 13/6271; H01R 12/52; H01R 12/716; H01R 13/02; H01R 13/514; H01R 13/629; H05K 7/20418

(57) ABSTRACT

A connector shell assembly comprises a shell and a radiator assembly. The shell has an opening and a slot hole formed in its top wall. The radiator assembly includes an elastic clip fixed to the shell and a radiator pressed onto the top of the shell by the elastic clip. A contact protrusion and a support protrusion are formed on the bottom surface of a base of the radiator. The contact protrusion protrudes into the interior of the shell through the opening and is adapted for thermal contact with a mating connector inserted into the shell under the pressing of the elastic clip. The radiator is movable from a pre-installation position to a final installation position along the longitudinal direction of the shell under a bias of the inserted mating connector.

### CROSS-REFERENCE TO RELATED APPLICATION

This application claims the benefit of Chinese Patent Application No. CN202410573727.2 filed on May 9, 2024 in the State Intellectual Property Office of China, the whole disclosure of which is incorporated herein by reference.

### FIELD OF THE DISCLOSURE

The present disclosure relates to a connector shell assembly, a connector comprising the connector shell assembly and a connector assembly comprising the connector.

### BACKGROUND OF THE INVENTION

In the prior art, in order to improve the heat dissipation of connector, a radiator is usually installed on the top wall of the connector shell. The base of the radiator has a protrusion into the shell, which is used for thermal contact with the mating connector inserted into the shell. In order to ensure reliable thermal contact, an elastic clip is usually installed on the shell, which applies downward pressure on the top of the radiator to provide a predetermined contact force between the protrusion of the radiator base and the inserted mating connector. This contact force is usually relatively large, which leads to a large frictional force between the protrusion of the radiator base and the inserted mating connector. This will cause severe wear on the protrusion of the radiator base, which will reduce the thermal contact performance between the radiator and the mating connector, thereby reducing the heat dissipation performance of the connector.

### SUMMARY OF THE INVENTION

According to an embodiment of the present disclosure, a connector shell assembly comprises a shell and a radiator assembly. The shell has an opening and a slot hole formed in its top wall. The radiator assembly includes an elastic clip fixed to the shell and a radiator pressed onto the top of the shell by the elastic clip. A contact protrusion and a support protrusion are formed on the bottom surface of a base of the radiator. The contact protrusion protrudes into the interior of the shell through the opening and is adapted for thermal contact with a mating connector inserted into the shell under the pressing of the elastic clip. The radiator is movable from a pre-installation position to a final installation position along the longitudinal direction of the shell under the push of the inserted mating connector. When the radiator is in the pre-installation position, the support protrusion is pressed against the outer side of the top wall of the shell, causing the contact protrusion to be lifted upward to a first position, so as not to contact the inserted mating connector or the contact force is slightly greater than zero. When the radiator is moved to the final installation position, the support protrusion engages with the slot hole on the top wall of the shell, causing the contact protrusion to fall to a second position lower than the first position to contact the inserted mating connector with a contact force not less than a preset value.

### DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1 shows an illustrative perspective view of a connector shell assembly according to an exemplary embodiment of the present invention;

FIG. 2 shows an illustrative perspective view of the radiator of the connector shell assembly according to an exemplary embodiment of the present invention when viewed from the top;

FIG. 3 shows an illustrative perspective view of the radiator of the connector shell assembly according to an exemplary embodiment of the present invention when viewed from the bottom;

FIG. 4 shows an illustrative perspective view of a radiator assembly of a connector shell assembly according to an exemplary embodiment of the present invention;

FIG. 5 shows an illustrative perspective view of an elastic clip of a radiator assembly according to an exemplary embodiment of the present invention;

FIG. 6 shows an illustrative exploded view of the elastic clip of a radiator assembly according to an exemplary embodiment of the present invention;

FIG. 7 shows an illustrative perspective view of the base of the radiator and the limit member of the elastic clip according to an exemplary embodiment of the present invention;

FIG. 8 shows an illustrative perspective view of the base of a radiator and the shell of a connector according to an exemplary embodiment of the present invention;

FIG. 9 shows an illustrative exploded view of the base of a radiator and the shell of a connector according to an exemplary embodiment of the present invention;

FIG. 10 shows a longitudinal sectional view of a connector shell assembly according to an exemplary embodiment of the present invention, with the radiator in a pre-installation position;

FIG. 11 shows a schematic diagram of the mating connector inserted into the shell of the connector shell assembly shown in FIG. 10, with the radiator in the pre-installation position;

FIG. 12 shows a longitudinal sectional view of a connector shell assembly and an inserted mating connector according to an exemplary embodiment of the present invention, with the radiator in a pre-installation position;

FIG. 13 shows a an illustrative partially enlarged view of the connector shell assembly and the inserted mating connector shown in FIG. 12, with the radiator in the pre-installation position;

FIG. 14 shows an illustrative perspective view of a connector shell assembly and an inserted mating connector according to an exemplary embodiment of the present invention, with the radiator in the final installation position;

FIG. 15 shows a longitudinal sectional view of a connector shell assembly and an inserted mating connector according to an exemplary embodiment of the present invention, with the radiator in the final installation position; and

FIG. 16 shows a an illustrative partially enlarged view of the connector shell assembly and the inserted mating connector shown in FIG. 15, with the radiator in the final installation position.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment of the present disclosure, a connector shell assembly comprises: a shell having an opening and a slot hole formed in its top wall; and a radiator assembly comprising an elastic clip fixed to the shell and a radiator pressed onto the top of the shell by the elastic clip. A contact protrusion and a support protrusion are formed on the bottom surface of a base of the radiator, the contact protrusion protrudes into the interior of the shell through the opening and is suitable for thermal contact with a mating connector inserted into the shell under the pressing of the elastic clip. The radiator can be moved from a pre-installation position to a final installation position along the longitudinal direction of the shell under the push of the inserted mating connector. When the radiator is in the pre-installation position, the support protrusion is pressed against the outer side of the top wall of the shell, causing the contact protrusion to be lifted upward to a first position, so as not to contact the inserted mating connector or the contact force is slightly greater than zero. When the radiator is moved to the final installation position, the support protrusion engages with the slot hole on the top wall of the shell, causing the contact protrusion to fall to a second position lower than the first position to contact the inserted mating connector with a contact force not less than a preset value.

According to another embodiment of the present disclosure, a connector comprises the above connector shell assembly, and a terminal module which is installed in the shell, for mating with a mating connector inserted into the shell.

According to another embodiment of the present disclosure, a connector assembly comprises the above connector, and a mating connector inserted into the shell of the connector to mate with the connector.

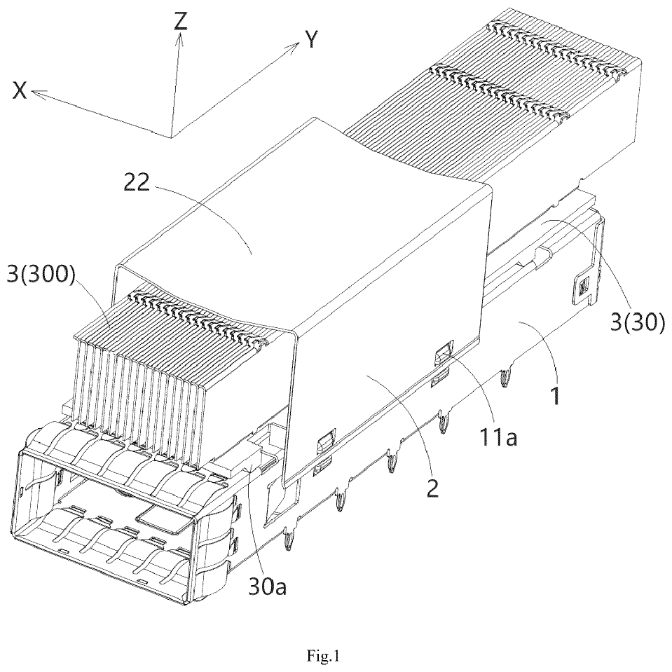

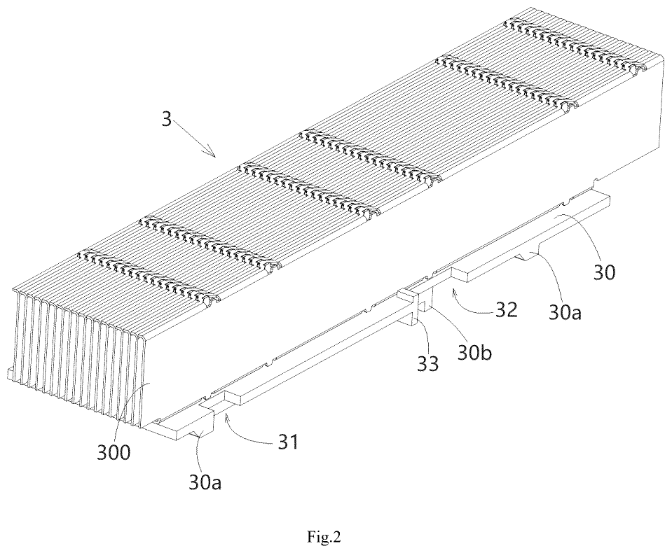

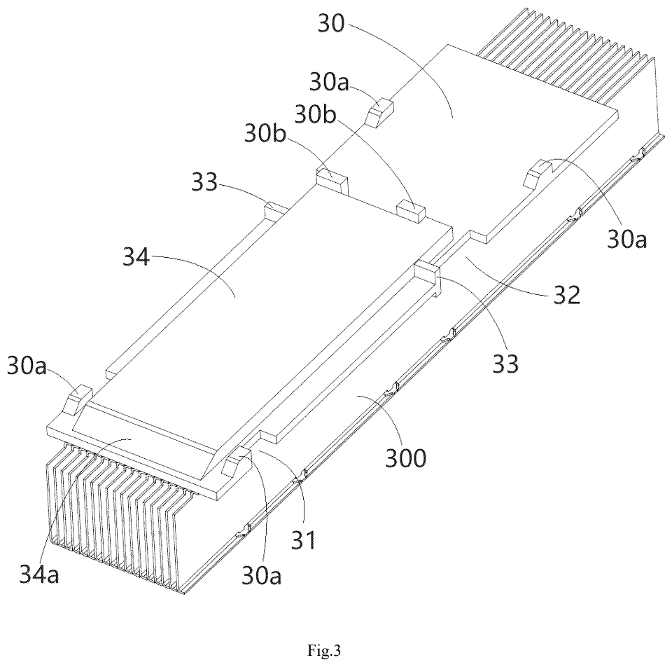

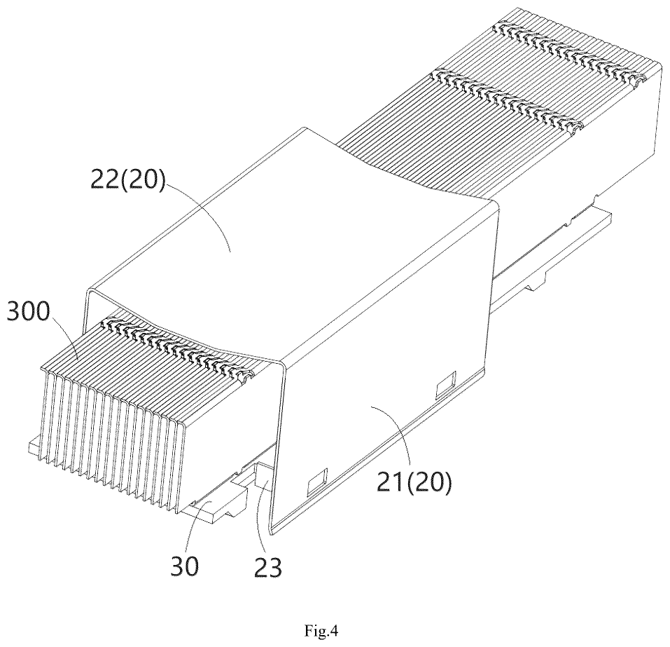

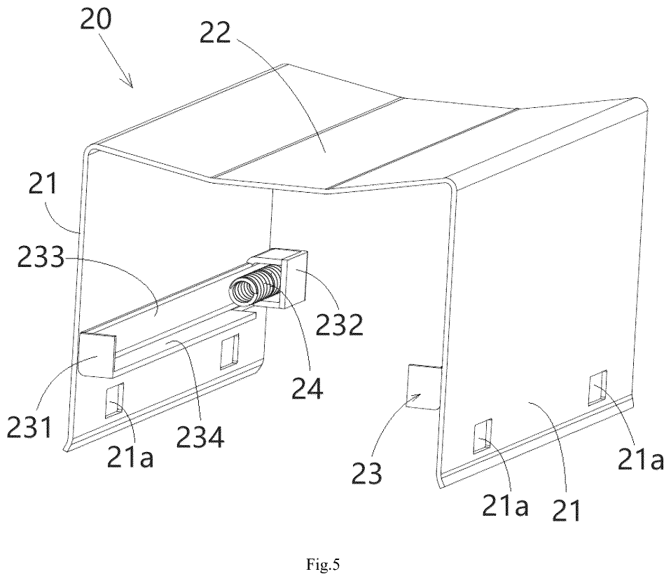

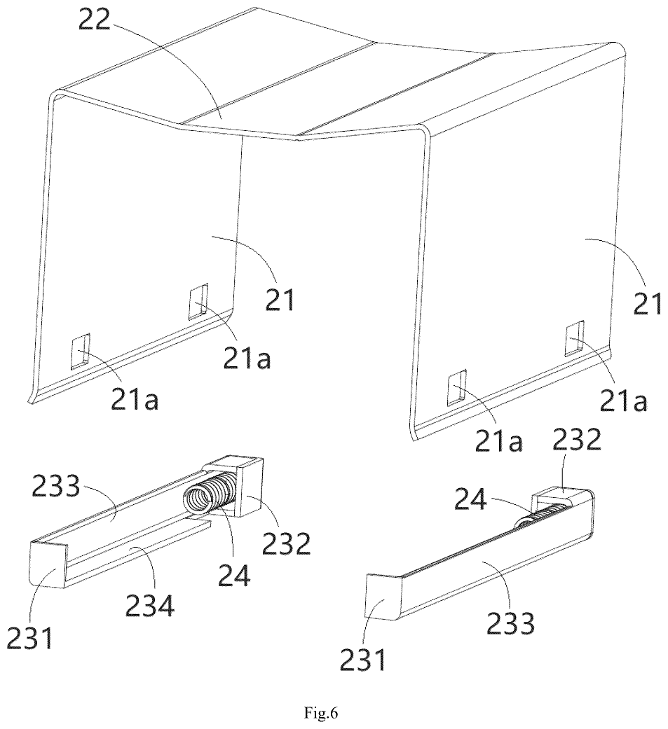

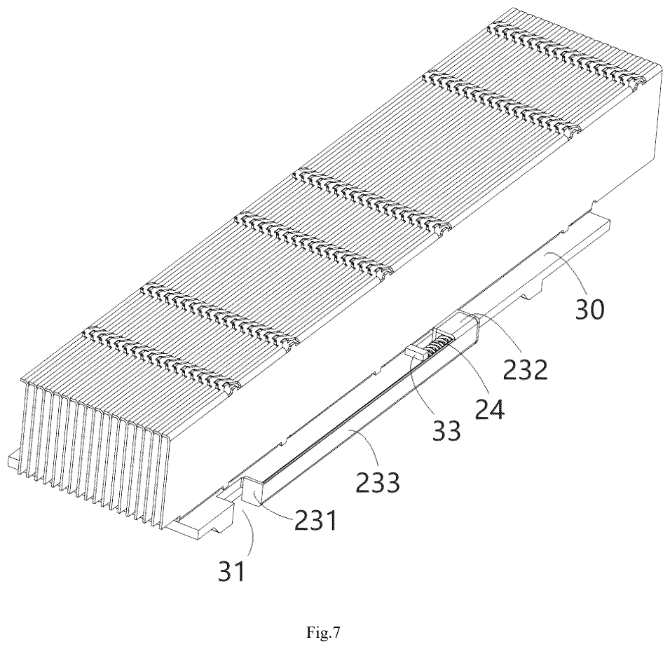

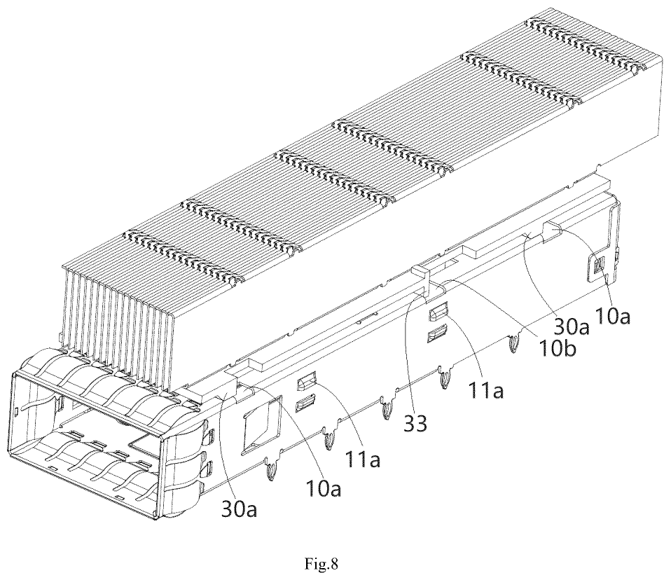

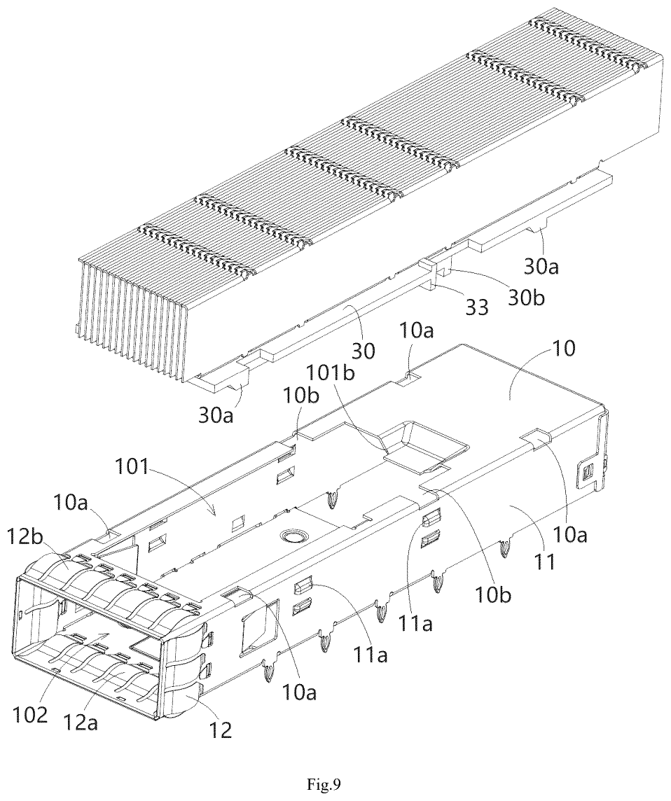

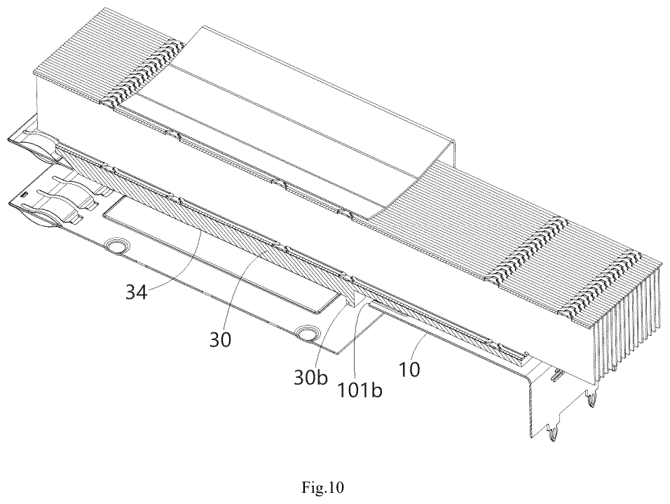

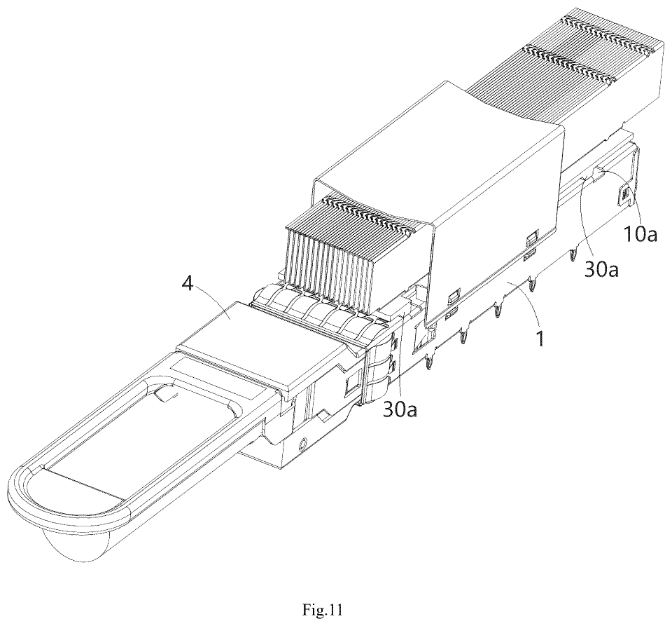

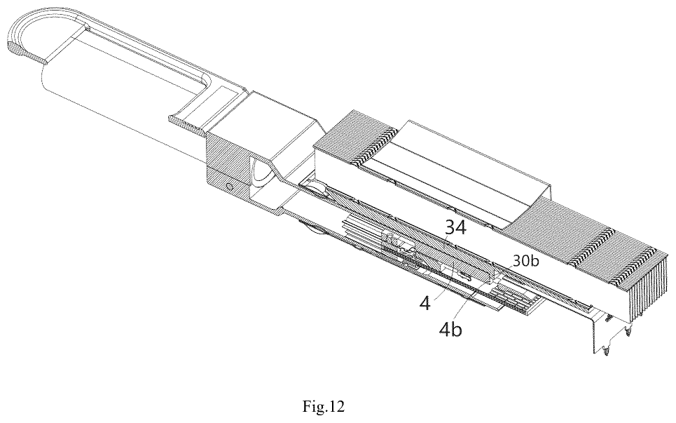

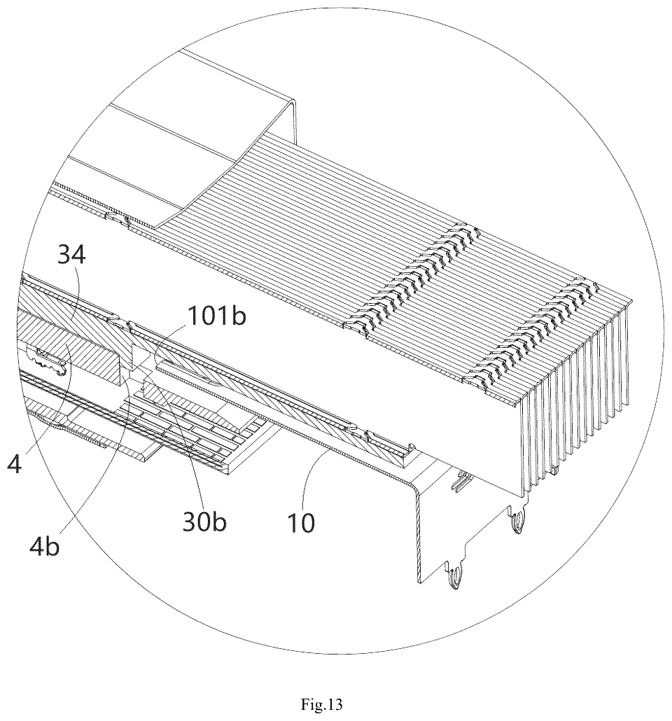

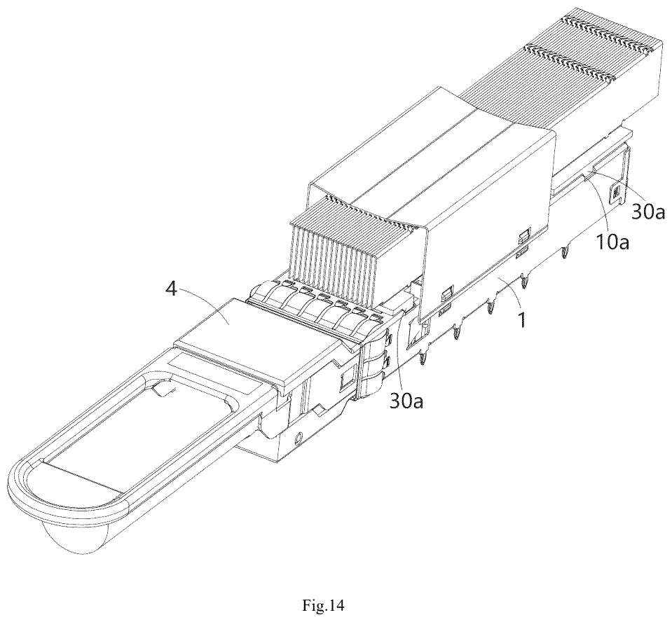

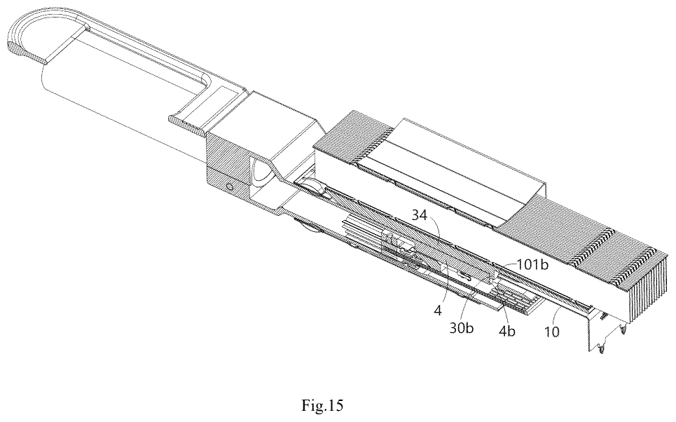

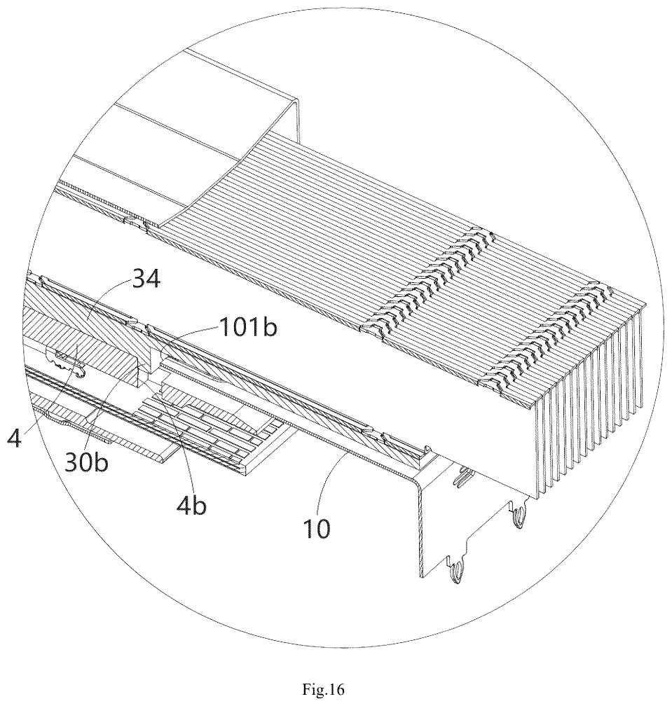

FIG. 1 shows an illustrative perspective view of a connector shell assembly according to an exemplary embodiment of the present invention. FIG. 2 shows an illustrative perspective view of the radiator 3 of the connector shell assembly according to an exemplary embodiment of the present invention when viewed from the top. FIG. 3 shows an illustrative perspective view of the radiator 3 of the connector shell assembly according to an exemplary embodiment of the present invention when viewed from the bottom. FIG. 4 shows an illustrative perspective view of a radiator assembly of a connector shell assembly according to an exemplary embodiment of the present invention. FIG. 5 shows an illustrative perspective view of the elastic clip 2 of a radiator assembly according to an exemplary embodiment of the present invention. FIG. 6 shows an illustrative exploded view of the elastic clip 2 of the radiator assembly according to an exemplary embodiment of the present invention. FIG. 7 shows an illustrative perspective view of the base 30 of the radiator 3 and the limit member 23 of the elastic clip 2 according to an exemplary embodiment of the present invention. FIG. 8 shows an illustrative perspective view of the base 30 of the radiator 3 and the shell 1 of the connector according to an exemplary embodiment of the present invention. FIG. 9 shows an illustrative exploded view of the base 30 of the radiator 3 and the shell 1 of the connector according to an exemplary embodiment of the present invention. FIG. 10 shows a longitudinal sectional view of a connector shell assembly according to an exemplary embodiment of the present invention, wherein the radiator 3 is in a pre-installation position. FIG. 11 shows a schematic diagram of the mating connector 4 inserted into the shell 1 of the connector shell assembly shown in FIG. 10, with the radiator 3 in the pre-installation position. FIG. 12 shows a longitudinal sectional view of a connector shell assembly and an inserted mating connector 4 according to an exemplary embodiment of the present invention, with the radiator 3 in a pre-installation position. FIG. 13 shows a an illustrative partially enlarged view of the connector shell assembly and the inserted mating connector 4 shown in FIG. 12, with the radiator 3 in the pre-installation position. FIG. 14 shows an illustrative perspective view of a connector shell assembly and an inserted mating connector 4 according to an exemplary embodiment of the present invention, with the radiator 3 in the final installation position. FIG. 15 shows a longitudinal sectional view of a connector shell assembly and an inserted mating connector 4 according to an exemplary embodiment of the present invention, with the radiator 3 in the final installation position. FIG. 16 shows a an illustrative partially enlarged view of the connector shell assembly and the inserted mating connector 4 shown in FIG. 15, with the radiator 3 in the final installation position.

As shown in FIGS. 1-16, in an exemplary embodiment of the present invention, a connector shell assembly is disclosed. The connector shell assembly includes: a shell 1 and a radiator assembly 2, 3. An opening 101 and a slot hole 10a are formed in the top wall 10 of the shell 1. The radiator assembly 2, 3 include an elastic clip 2 fixed to the shell 1 and a radiator 3 pressed against the top of the shell 1 by the elastic clip 2. A contact protrusion 34 and a support protrusion 30a are formed on the bottom surface of the base 30 of the radiator 3. The contact protrusion 34 protrudes into the interior of the shell 1 through the opening 101 on the top wall 10 of the shell 1 and is suitable for thermal contact with a mating connector 4 inserted into the shell 1 under the pressure of the elastic clip 2. The radiator 3 can be moved along the longitudinal direction Y of the shell 1 from a pre-installation position (the position shown in FIGS. 11 to 13) to a final installation position (the position shown in FIGS. 14 to 16) under the push of the inserted mating connector 4.

As shown in FIGS. 11-13, in the illustrated embodiment, when the radiator 3 is in the pre-installation position, the support protrusion 30a is pressed against the outer side of the top wall 10 of the shell 1, so that the contact protrusion 34 is lifted upward to a first position, so as not to contact the inserted mating connector 4 or the contact force is slightly greater than zero. In this way, it can prevent the contact protrusion 34 of the radiator 3 from being worn by the mating connector 4 that is inserted.

As shown in FIGS. 14-16, in the illustrated embodiment, when the radiator 3 is moved to the final installation position, the support protrusion 30a engages with the slot hole 10a in the top wall 10 of the shell 1, causing the contact protrusion 34 to fall to a second position lower than the first position to make contact with the inserted mating connector 4 with a contact force not less than a preset value. In this way, it can ensure reliable thermal contact between the contact protrusion 34 of the radiator 3 and the inserted mating connector 4.

Referring again to FIGS. 1-16, in the illustrated embodiment, a limit protrusion 30b is also formed on the bottom surface of the base 30 of the radiator 3, which has front and rear sides opposite to each other in the longitudinal direction Y of the shell 1. When the radiator 3 is moved to the final installation position, the rear side of the limit protrusion 30b is pressed against the rear side edge 19b of the opening 101 of the shell 1 to keep the radiator 3 in the final installation position.

The front side of the limit protrusion 30b is used to rest against the stepped portion of the inserted mating connector 4, so that the mating connector 4 can push the radiator 3 from the pre-installation position to the final installation position by pushing the limit protrusion 30b. The height of the limit protrusion 30b protruding from the bottom surface of the base 30 exceeds that of the contact protrusion 34, and the height of the contact protrusion 34 protruding from the bottom surface of the base 30 exceeds that of the support protrusion 30a.

The contact protrusion 34 has front and rear ends opposite to each other in the longitudinal direction Y of the shell 1, and the limit protrusion 30b is connected or adjacent to the rear end of the contact protrusion 34. A guide slope 34a is formed on the front end of the contact protrusion 34, which is used to guide the mating connector 4 into the shell 1.

The base 30 of the radiator 3 has front and rear ends opposite to each other in the longitudinal direction Y of the shell 1 and two sides opposite to each other in the transverse direction X of the shell 1. Support protrusions 30a are respectively formed on the bottom surfaces of the front and rear ends of the two side portions of the base 30.

The shell 1 has a front port 102 that allows the mating connector 4 to be inserted, and an elastic contact member 12 is provided on the peripheral wall of the front port 102 of the shell 1. The elastic contact member 12 has an outer contact spring piece 12b located outside the shell 1 and an inner contact spring piece 12a located inside the shell 1. The inner contact spring pieces 12a of the elastic contact 12 are used to make electrical contact with the outer side of the inserted mating connector 4, and the outer contact spring pieces 12b of the elastic contact 12 are used to make electrical contact with the inner side of an installation hole of an installation panel (not shown).

The radiator assembly 2, 3 also includes a reset spring 24, which is compressed along the longitudinal direction Y of the shell 1 between the elastic clip 2 and the radiator 3. When the mating connector 4 is pulled out of the shell 1, the radiator 3 is adapted to be moved from the final installation position to the pre-installation position under the action of the reset spring 24.

The elastic clip 2 comprises an elastic clip body 20, which includes a pair of side plates 21 and a pressing spring piece 22 connected between the top of the pair of side plates 21. Snap slots 21a are respectively formed at the lower parts of the pair of side plates 21 of the elastic clip (2), and protrusions 11a for engaging with the snap slots 21a are respectively formed on the pair of side walls 11 of the shell 1, so as to fix the elastic clip 2 to the shell (1). The pressing spring piece 22 of the elastic clip 2 arches towards the top of the radiator 3 and presses onto the top of the radiator 3 to apply downward pressure to the radiator 3.

The elastic clip 2 further includes a pair of limit members 23, which are respectively fixed to the inner sides of the pair of side plates 21. The limit member 23 has front and rear ends opposite to each other in the longitudinal direction Y of the shell 1, and includes a limiting end plate 231 located at its front end. A first notch 31 is formed on the side of the base 30 of the radiator 3, and the limiting end plate 231 is accommodated in the first notch 31. When the radiator 3 is in the pre-installation position, the limiting end plate 231 is pressed against the rear edge of the first notch 31 to keep the radiator 3 in the pre-installation position.

The limit member 23 further includes a limiting end cap 232 located at its rear end, and the rear end of the reset spring 24 is accommodated and positioned in the limiting end cap 232. A second notch 32 is formed on the side of the base 30 of the radiator 3, and the limit end cap 232 and the reset spring 24 are accommodated in the second notch 32. A limit plate 33 protruding upwards and downwards is formed on the front side of the second notch 32, and the front end of the reset spring 24 is pressed against the limit plate 33. An avoidance slot 10b is formed in the top wall 10 of the shell 1 to avoid the limit plate 33.

The limit member 23 further comprises a vertical plate 233 and a horizontal plate 234. The vertical plate 233 extends along the longitudinal direction Y of the shell 1 and is welded to the inner side of the side plate 21. The horizontal plate 234 is connected to the lower side of the vertical plate 233 and extends along the longitudinal direction Y of the shell 1. The front ends of vertical plate 233 and horizontal plate 234 are connected to limit end plate 231, and the rear end of vertical plate 233 is connected to limit end cap 232. The vertical plate 233 is suitable for resting against the side of the base 30 of the radiator 3, and the horizontal plate 234 is suitable for resting against the bottom surface of the side of the base 30 of the radiator 3.

When the radiator assembly 2, 3 is installed on the shell 1, the horizontal plate 234 of the limit member 23 does not contact the bottom surface of the side edge of the base 30 of the radiator 3, allowing the base 30 of the radiator 3 to be lifted up to the first position or dropped to the second position. Before the radiator assembly 2, 3 are installed on the shell 1, the horizontal plate 234 of the limit member 23 contacts the bottom surface of the side edge of the base 30 of the radiator 3, so that the radiator 3 is clamped between the pressing spring piece 22 of the elastic clip 2 and the horizontal plate 234 of the limit member 23. In this way, the elastic clip 2 and the radiator 3 can be pre-assembled into the radiator assembly 2, 3. The radiator 3 includes multiple heat dissipation fins 300, which are welded to the top surface of the base 30 and arranged along the transverse direction X of the base 30. The pressing spring piece 22 of the elastic clip 2 presses on the top of the heat dissipation fins 300.

In another exemplary embodiment of the present invention, a connector is also disclosed. The connector includes a connector shell assembly and a terminal module. The terminal module is installed in the shell 1 for mating with the inserted mating connector 4.

The terminal module comprises an insulator (not shown) and terminals (not shown), with the terminals arranged within the insulator. One end of the terminal is used for mating with the mating terminal of the inserted mating connector 4, and the other end is used for electrical connection to a circuit board.

In another exemplary embodiment of the present invention, a connector assembly is also disclosed. The connector assembly includes: a connector and a mating connector 4. The mating connector 4 is inserted into the shell 1 of the connector to mate with the connector. The connector assembly further comprises a circuit board, and the bottom of the connector shell 1 is fixed to the circuit board. One end of the connector terminal is mated with the mating terminal of the inserted mating connector 4, and the other end is electrically connected to the circuit board.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A connector shell assembly, comprising:
a shell having an opening and a slot hole formed in its top wall; and
a radiator assembly including an elastic clip fixed to the shell and a radiator pressed onto the top of the shell by the elastic clip, a contact protrusion and a support protrusion are formed on the bottom surface of a base of the radiator, the contact protrusion protrudes into the interior of the shell through the opening and is adapted for thermal contact with a mating connector inserted into the shell under a force of the elastic clip, wherein:
the radiator is movable from a pre-installation position to a final installation position along the longitudinal direction of the shell under a bias of the inserted mating connector;
when the radiator is in the pre-installation position, the support protrusion is pressed against the outer side of the top wall of the shell, causing the contact protrusion to be lifted upward to a first position, so as not to contact the inserted mating connector or the contact force is slightly greater than zero;
when the radiator is moved to the final installation position, the support protrusion engages with the slot hole on the top wall of the shell, causing the contact protrusion to fall to a second position lower than the first position to contact the inserted mating connector with a contact force not less than a preset value.

2. The connector shell assembly according to claim 1, wherein:
a limit protrusion is formed on the bottom surface of the base of the radiator, the limit protrusion has front and rear sides opposite to each other in the longitudinal direction of the shell; and
when the radiator is moved to the final installation position, the rear side of the limit protrusion is pressed against the rear side edge of the opening of the shell to keep the radiator in the final installation position.

3. The connector shell assembly according to claim 2, wherein the front side of the limit protrusion is adapted to rest against the stepped portion of the inserted mating connector, so that the mating connector can push the radiator from the pre-installation position to the final installation position by pushing the limit protrusion.

4. The connector shell assembly according to claim 3, wherein the height of the limit protrusion protruding from the bottom surface of the base exceeds that of the contact protrusion, and the height of the contact protrusion protruding from the bottom surface of the base exceeds that of the support protrusion.

5. The connector shell assembly according to claim 3, wherein:
the contact protrusion has front and rear ends opposite to each other in the longitudinal direction of the shell, and the limit protrusion is connected or adjacent to the rear end of the contact protrusion; and
a guide slope is formed on the front end of the contact protrusion, which is used to guide the mating connector into the shell.

6. The connector shell assembly according to claim 1, wherein the base of the radiator has front and rear ends opposite to each other in the longitudinal direction of the shell and two sides opposite to each other in the transverse direction of the shell, support protrusions are respectively formed on the bottom surfaces of the front and rear ends of the two side edges of the base.

7. The connector shell assembly according to claim 1, wherein:
the shell has a front port that allows the mating connector to be inserted, and an elastic contact member is provided on the peripheral wall of the front port of the shell, the elastic contact member has an outer contact spring piece located outside the shell and an inner contact spring piece located inside the shell; and
the inner contact spring pieces of the elastic contact member are used to make electrical contact with the outer side of the inserted mating connector, and the outer contact spring pieces of the elastic contact member are used to make electrical contact with an inner side of an installation hole of an installation panel.

8. The connector shell assembly according to claim 1, wherein:
the radiator assembly further comprises a reset spring, which is compressed along the longitudinal direction of the shell between the elastic clip and the radiator; and
when the mating connector is pulled out of the shell, the radiator is adapted to be moved from the final installation position to the pre-installation position under the action of the reset spring.

9. The connector shell assembly according to claim 7, wherein:
the elastic clip comprises an elastic clip body, which includes a pair of side plates and a pressing spring piece connected between the top of the pair of side plates;
snap slots are respectively formed at the lower parts of the pair of side plates of the elastic clip, and protrusions for engaging with the snap slots are respectively formed on the pair of side walls of the shell, so as to fix the elastic clip to the shell; and
the pressing spring piece of the elastic clip arches towards the top of the radiator and presses onto the top of the radiator to apply a downward pressing force to the radiator.

10. The connector shell assembly according to claim 9, wherein the elastic clip further comprises a pair of limit members which are respectively fixed to the inner sides of the pair of side plates, wherein:
the limit member has front and rear ends opposite to each other in the longitudinal direction of the shell, and the limit member comprises a limiting end plate located at its front end;
a first notch is formed on the side edge of the base of the radiator, and the limiting end plate is accommodated in the first notch; and
when the radiator is in the pre-installation position, the limiting end plate rests against the rear side edge of the first notch to keep the radiator in the pre-installation position.

11. The connector shell assembly according to claim 10, wherein:
the limit member further comprises a limiting end cap located at its rear end, and the rear end of the reset spring is accommodated and positioned in the limiting end cap;
a second notch is formed on the side edge of the base of the radiator, and the limit end cap and the reset spring are accommodated in the second notch; and
a limit plate protruding upwards and downwards is formed on the front side of the second notch, and the front end of the reset spring is pressed against the limit plate, an avoidance slot is formed in the top wall of the shell to avoid the limit plate.

12. The connector shell assembly according to claim 11, wherein the limit member further comprises:
a vertical plate extending along the longitudinal direction of the shell and welded to the inner side of the side plate; and
a horizontal plate connected to the lower side of the vertical plate and extending along the longitudinal direction of the shell.

13. The connector shell assembly according to claim 12, wherein the front ends of the vertical plate and the horizontal plate are connected to the limit end plate, and the rear end of the vertical plate is connected to the limit end cap, the vertical plate is adapted to rest on the side of the base of the radiator, and the horizontal plate is adapted to rest on the bottom surface of the side of the base of the radiator.

14. The connector shell assembly according to claim 13, wherein when the radiator assembly are installed on the shell, the horizontal plate of the limit member does not contact the bottom surface of the side edge of the base of the radiator, allowing the base of the radiator to be lifted up to the first position or lowered to the second position.

15. The connector shell assembly according to claim 13, wherein when the radiator assembly have not been installed on the shell, the horizontal plate of the limit member contacts the bottom surface of the side edge of the base of the radiator, so that the radiator is clamped between the pressing spring piece of the elastic clip and the horizontal plate of the limit member.

16. The connector shell assembly according to claim 9, wherein the radiator comprises multiple heat dissipation fins, which are welded to the top surface of the base and arranged along the transverse direction of the base, the pressing spring piece of the elastic clip presses on the top of the heat dissipation fins.

17. A connector, comprising:
the connector shell assembly according to claim 1; and
a terminal module installed in the shell, and adapted to mate with a mating connector inserted into the shell.

18. The connector according to claim 16, wherein the terminal module comprises:
an insulator; and
a terminal provided in the insulator, wherein one end of the terminal is used for mating with a mating terminal of the inserted mating connector, and the other end is used for electrical connection to a circuit board.

19. A connector assembly, comprising:
the connector according to claim 18; and
a mating connector inserted into the shell of the connector to mate with the connector.

20. The connector assembly according to claim 19, further comprising a circuit board, on which the bottom of the shell of the connector is fixed, wherein one end of the terminal of the connector is mated with the mating terminal of the mating connector, and the other end is electrically connected to the circuit board.
